(19) United States
(12) Patent Application Publication
(10) Pub. No.: US 2024/0345273 A1
(43) Pub. Date: Oct. 17, 2024

(54) PROPAGATION OF PETROPHYSICAL PROPERTIES TO WELLS IN A FIELD

(71) Applicant: Schlumberger Technology Corporation, Sugar Land, TX (US)

(72) Inventors: Vasileios-Marios Gkortsas, Boston, MA (US); Lalitha Venkataramanan, Lexington, MA (US); Smaine Zeroug, Lexington, MA (US); Harish Baban Datir, Tananger (NO)

(21) Appl. No.: 18/580,196

(22) PCT Filed: Jul. 21, 2022
(86) PCT No.: PCT/US2022/074018

§ 371 Date: Jan. 18, 2024

Related U.S. Application Data
(60) Provisional application No. 63/224,141, filed on Jul. 21, 2021.

(51) Int. Cl. G01V 1/30; G01V 1/50

(52) U.S. Cl. CPC G01V 1/306; G01V 1/50; G01V 2210/6244; G01V 2210/6246

(57) ABSTRACT

Embodiments of the disclosure provide a method to propagate a set of petrophysical measurements in at least one well to a well not having a full set of petrophysical measurements. The method includes identifying a first data set for a first well. The method also includes identifying a second data set for a second well. Using a mapping derived from the first well, the petrophysical property for measurement A can be derived for the second well from measurement B of the second well.

### CROSS-REFERENCE TO RELATED APPLICATIONS

The current application claims priority to U.S. Provisional Application 63/224,141, dated Jul. 21, 2021 the entirety of which is incorporated by reference.

### FIELD OF THE INVENTION

Aspects of the disclosure relate to propagating a set of petrophysical measurements (or properties) in at least one well to a well not having the same set of petrophysical measurements.

### BACKGROUND INFORMATION

The present disclosure generally relates to propagating a set of petrophysical measurements (or properties) in at least one well to a well not having the same set of petrophysical measurements.

In an oil and gas field or basin, the same data is not available in all the wells. Often, operators drill exploratory wells to identify the presence of hydrocarbons within the geological stratum. In some instances, a first exploratory well may discover a feature or geological characteristic that could be potentially valuable. A second exploratory well can use more precise equipment to further evaluate the geological properties of the stratum. Thus, exploratory wells often have both low- and high-resolution information as well as different information among a group of wells.

An example of the above situation may be found in other situations as follows. Exploratory wells in a field may have a wide range of measurements: logging-while-drilling (LWD) logs as well as low- and high-resolution wireline logs. An example of often acquired wireline logs includes gamma ray, resistivity, neutron and density measurements. Examples of high-resolution wireline measurements are the nuclear magnetic resonance (NMR), dielectric, sonic and detailed elemental information measurements. The high-resolution information allows the user to understand and compute a detailed set of rock formation petrophysical properties. On the other instances, development wells may have only a subset of these measurements in order to save economic costs. As used herein, the term “resolution” is used here to mean both the spatial resolution of a measurement as it relates to the scale of rock heterogeneities as well as sensitivity resolution to specific physical parameters. The latter may also be referred to the “fidelity” of a measurement to render information on certain physical parameters.

When a complete set of data in each well is not present, it may be advantageous to identify as many characteristics of a well that has been drilled as possible. Conventional analysis does not provide the capability to identify characteristics of well from another well.

There is a need to be able to propagate a detailed set of petrophysical measurements or properties to all the wells in the field. This serves multiple purposes. First, this information allows the user to derive actionable insights in wells where measurement is not available. Second, it allows the user to build a reservoir model or a set of models that can subsequently be used for prediction. Lastly, it expands the understanding of the value of information/a measurement or service in wells.

There is a need to provide an apparatus and methods that easier to operate than conventional apparatus and methods so that the detailed set of petrophysical measurements may be determined.

There is a further need to provide apparatus and methods that do not have the drawbacks discussed above, namely the costly drilling and high resolution measurements required for each well in an area.

There is a still further need to better use already created downhole tools to deduce the characteristics of a well without repetitive analysis to ultimately reduce economic costs associated with operations and apparatus described above with conventional tools and conventional analysis.

There is a still further need to allow for such derivation of characteristics of a well in an area using known techniques without specialized equipment.

### SUMMARY

So that the manner in which the above recited features of the present disclosure can be understood in detail, a more particular description of the disclosure, briefly summarized below, may be had by reference to embodiments, some of which are illustrated in the drawings. It is to be noted that the drawings illustrate only typical embodiments of this disclosure and are therefore not to be considered limiting of its scope, for the disclosure may admit to other equally effective embodiments without specific recitation. Accordingly, the following summary provides just a few aspects of the description and should not be used to limit the described embodiments to a single concept.

In an embodiment, a method of deriving measurements for at least one well, includes identifying a first data set for a first well. The first data set includes at least measurement A and measurement B, wherein measurement A provides a property of interest. The method also includes identifying a second data set for a second well. The second data set includes measurement B. The method further includes mapping the measurement B with measurement A of the first well to derive the property of interest from measurement B for the first well. The method also includes deriving the property of interest for measurement A for the second well from measurement B of the second well.

In one example embodiment, a method of deriving a geological parameter for wells in a field is described. The method may comprise identifying a first data set for at least two first wells that comprises at least a measurement A and a measurement B, wherein the measurement A is a property of interest. The method may also comprise identifying a second data set for at least one second well in the same field, wherein the second set of data comprises a measurement B for the second well. The method may also comprise developing a mapping the measurement B of the at least two first wells with the measurement A of the first two wells in order to derive a property of interest of the first well. The method may also comprise deriving a property of interest for a measurement A for the at least one second well in the same field from the measurement B of the at least one second well using the mapping developed.

### BRIEF DESCRIPTION OF THE FIGURES

So that the manner in which the above recited features of the present disclosure can be understood in detail, a more particular description of the disclosure, briefly summarized above, may be had by reference to embodiments, some of which are illustrated in the drawings. It is to be noted, however, that the appended drawings illustrate only typical embodiments of this disclosure and are therefore not be considered limiting of its scope, for the disclosure may admit to other equally effective embodiments.

FIG. 1 illustrates a workflow to propagate petrophysical properties to different wells in a field.

FIG. 2 illustrates a determined mapping function and permeability, according to an embodiment of the disclosure.

FIG. 3 shows the comparison of the estimated permeability and derived synthetic permeability, according to an embodiment of the disclosure.

FIG. 4 shows examples of the derived synthetic permeability and a satisfactory similarity with the estimated permeability, according to an embodiment of the disclosure.

FIG. 5 shows examples of the similarity between the derived synthetic permeability and the estimated permeability (ML_perm) that is not satisfactory, according to an embodiment of the disclosure.

To facilitate understanding, identical reference numerals have been used, where possible, to designate identical elements that are common to the figures (“FIGS”). It is contemplated that elements disclosed in one embodiment may be beneficially utilized on other embodiments without specific recitation.

### DETAILED DESCRIPTION

In the following, reference is made to embodiments of the disclosure. It should be understood, however, that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the claims except where explicitly recited in a claim. Likewise, reference to “the disclosure” shall not be construed as a generalization of inventive subject matter disclosed herein and should not be considered to be an element or limitation of the claims except where explicitly recited in a claim.

Although the terms first, second, third, etc., may be used herein to describe various elements, components, regions, layers and/or sections, these elements, components, regions, layers and/or sections should not be limited by these terms. These terms may be only used to distinguish one element, components, region, layer or section from another region, layer or section. Terms such as “first”, “second” and other numerical terms, when used herein, do not imply a sequence or order unless clearly indicated by the context. Thus, a first element, component, region, layer or section discussed herein could be termed a second element, component, region, layer or section without departing from the teachings of the example embodiments.

When an element or layer is referred to as being “on,” “engaged to,” “connected to,” or “coupled to” another element or layer, it may be directly on, engaged, connected, coupled to the other element or layer, or interleaving elements or layers may be present. In contrast, when an element is referred to as being “directly on,” “directly engaged to,” “directly connected to,” or “directly coupled to” another element or layer, there may be no interleaving elements or layers present. Other words used to describe the relationship between elements should be interpreted in a like fashion. As used herein, the term “and/or” includes any and all combinations of one or more of the associated listed terms.

Some embodiments will now be described with reference to the figures. Like elements in the various figures will be referenced with like numbers for consistency. In the following description, numerous details are set forth to provide an understanding of various embodiments and/or features. It will be understood, however, by those skilled in the art, that some embodiments may be practiced without many of these details, and that numerous variations or modifications from the described embodiments are possible. As used herein, the terms “above” and “below”, “up” and “down”, “upper” and “lower”, “upwardly” and “downwardly”, and other like terms indicating relative positions above or below a given point are used in this description to more clearly describe certain embodiments.

In one embodiment, a method of deriving measurements for at least one well, includes identifying a first data set for a first well. For purposes of description, the first well can be in the same field of the second well. The term “field” may include a single stratum or multiple stratum of hydrocarbon bearing materials. In example embodiments, the first well can also be an analog of the second well. The first data set for a first well includes at least measurement A and measurement B. For purposes of illustration, the measurements can be acoustic measurements, nuclear measurements, resistivity measurements, NMR, dielectric or combinations thereof. Measurement A in the data set provides a property of interest. The property of interest can be either permeability, saturation, clay volume, heterogeneity, anisotropy, elemental concentration, other petrophysical properties, or combinations thereof. In embodiments, the first well may be a plurality of wells, and wherein the first data set comprises a plurality of measurements A and measurements B for each well of the plurality of wells. In other embodiments, the first well may be a singular well. Thus, while describing a “first well”, pluralities of wells should be considered within the description provided.

The method also includes identifying a second data set for a second well. The second data set includes measurement B. The method further includes mapping the measurement B with measurement A of the first well to derive the property of interest from measurement B for the first well. The method also includes deriving the property of interest for measurement A for the second well from measurement B of the second well. Another embodiment includes obtaining an actual measurement A and property of interest for the second well and comparing the derived measurement A and derived property of interest for the second well to the actual measurement A and actual property of interest.

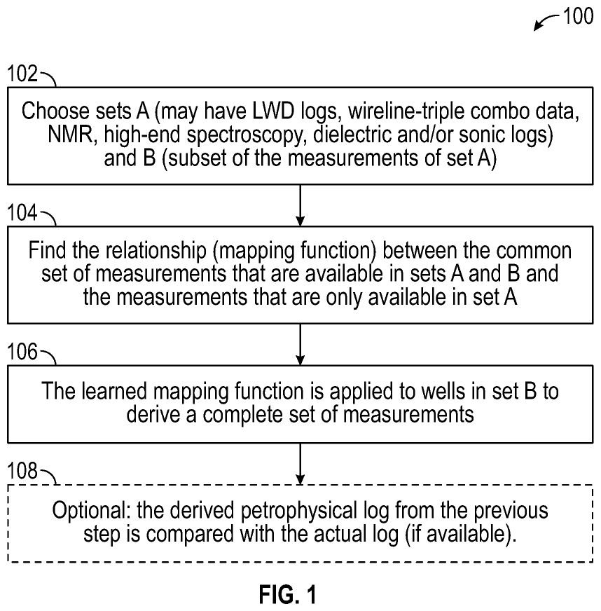

FIG. 1 is an example of an embodiment of a method 100 in one example embodiment of the disclosure. The embodiment of the method 100 in FIG. 1 is explained with reference to two set of wells. In this non-limiting embodiment, a first set of wells is referenced as set A and the second set of wells is referenced as set B. Wells in set A have a set of petrophysical measurements. Wells in set B have a subset of these petrophysical measurements. At 102, sets A and B are chosen. For example: wells in set A may have rich information comprised, for example of LWD, wireline-triple combo data, NMR, high-end spectroscopy, dielectric and/or sonic logs. Wells in set B may have a subset of these measurements.

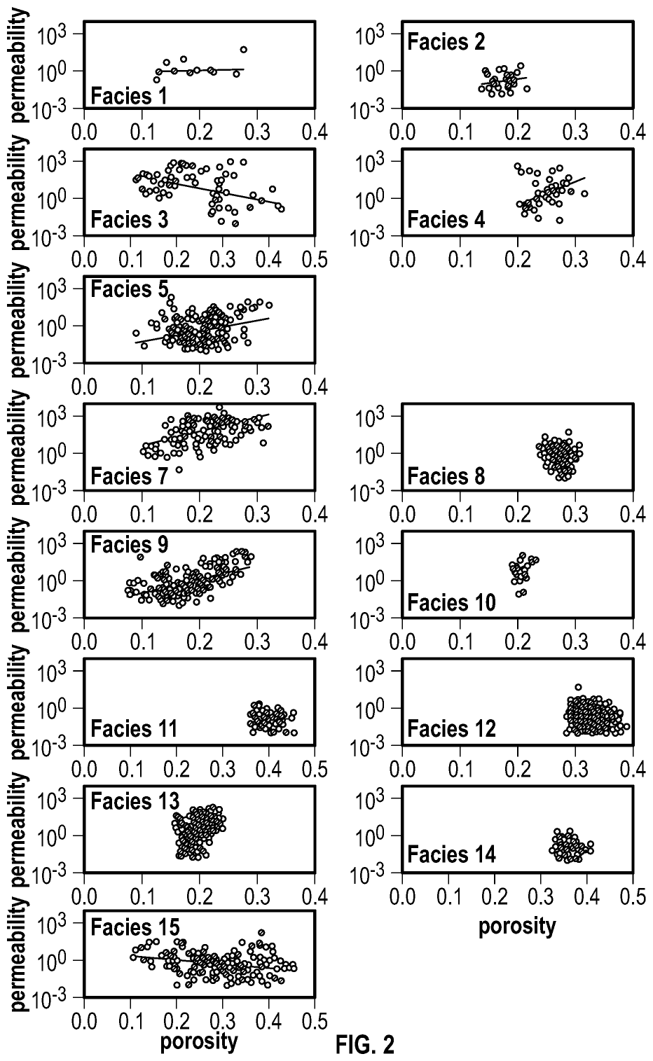

Next, at 104, a relation is found (learned mapping function) between the common set of measurements that are available in sets A and B and the measurements that are only available in set A, as seen in FIG. 2. In mathematical terms, this mapping function may be a linear or highly nonlinear mapping. In FIG. 1, at 106, the learned mapping function is applied to wells in set B to derive a complete set of measurements and/or properties for the wells in set B.

In one or more embodiments, the derived petrophysical log or petrophysical set of measurements can be compared, at 108, with the actual log (if available) of measurements for the wells in set B. This demonstrates the value of having an actual measurement in set B (as opposed to predicting the measurement). If the derived measurement is similar to the actual measurement, then it can be concluded that the actual measurement is not needed, and the learned mapping function is sufficient. If the contrary is true, it demonstrates the value of acquiring the actual measurement, and provides insight on the complexity of the rock formation as it reflects on the well completion and production decisions. As will be understood, the comparison performed at 108 is optional due to the availability of measurements.

For example, consider a field with 3 wells. All wells (labeled X, Y and Z) have both low and high-resolution petrophysical information/logs. In this example, the low-resolution logs are the triple combo set of logs, while the high-resolution petrophysical information is permeability derived from a combination of NMR and spectroscopy data. For the purpose of this example, we assume that well Z does not have the inferred permeability. Therefore, wells X and Y fall in set A and well Z is part of set B.

Next, the mapping function between the thermal neutron porosity (TNPH) from the triple combo logs and permeability in set A is learned. Using an electrofacies classification algorithm, a high dimensional clustering of the triple combo set of measurements is performed. Therefore, it is inferred that depth intervals in all wells that correspond to the same cluster and have the same set of properties. In this example, the electrofacies classification workflow, is used with density (RHOZ), thermal neutron porosity (TNPH) and gamma ray (HSGR) from wells X and Y as inputs.

In this embodiment, facies are obtained for each depth and perform a mapping to infer permeability from the thermal neutron porosity, for each facies separately, as seen in FIG. 2. Any other classification scheme with a different set or a subset of parameters can be used too.

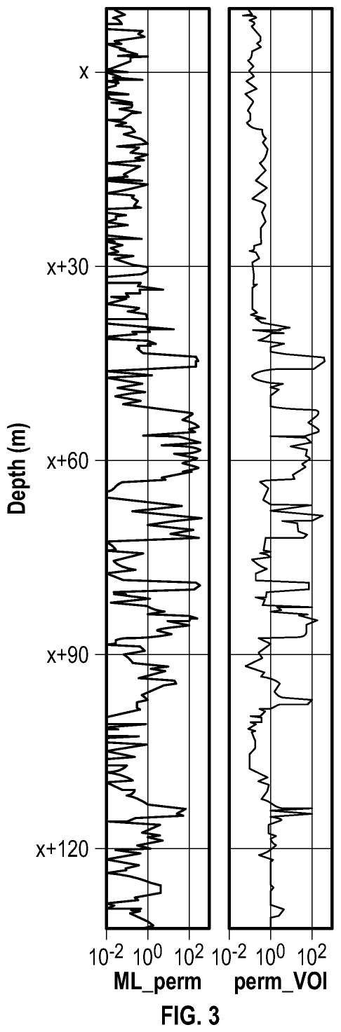

Next, the learned mapping of each facies is used to derive the corresponding synthetic (i.e., not an actual measurement of) permeability log in set B. FIG. 3 shows the derived synthetic permeability (column ‘perm_VOI’) and compares it with the estimated permeability in this well.

When comparing the derived synthetic permeability with the estimated measurement, the results show that for some depths the synthetic log shows a satisfactory similarity with the estimated measurement, while for other depths the existence of the estimated measurement is necessary and cannot be substituted.

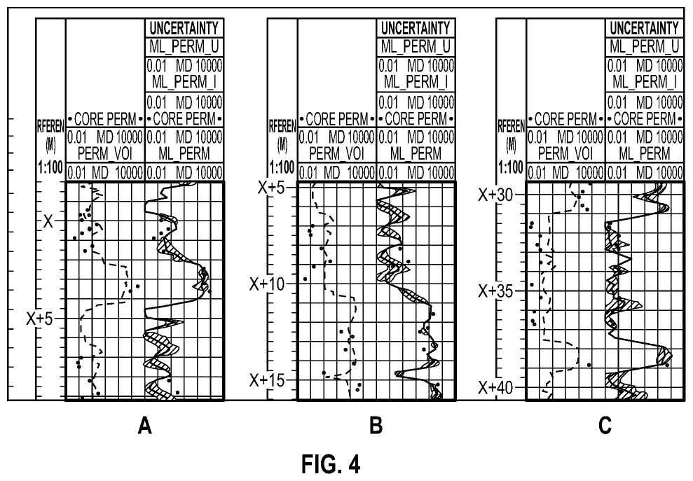

Referring to FIG. 4, three examples are shown where for some depths the synthetic permeability log (left panel) shows a satisfactory similarity with the estimated permeability log (on right panel).

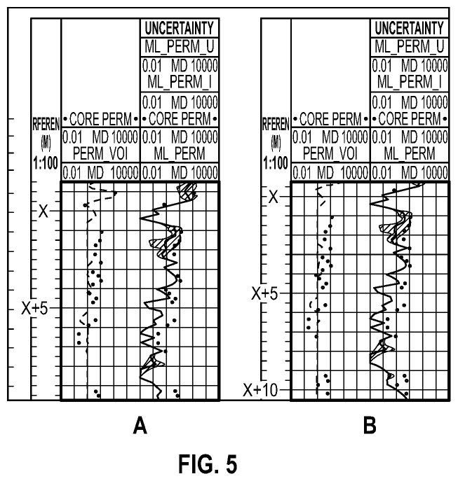

Referring to FIG. 5, two examples are shown where for some depths the similarity between the synthetic permeability log (left panel) and the estimated permeability log (right panel) is not satisfactory, making the existence of high-resolution measurements necessary.

Although this has been demonstrated on the permeability measurement, it can be used for any other set of measurements as well. For example, the set of petrophysical properties could be saturation, clay volume, heterogeneity, anisotropy, elemental concentration, other petrophysical properties, or combinations thereof.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and/or within less than 0.01% of the stated amount. As another example, in certain embodiments, the terms “generally parallel” and “substantially parallel” or “generally perpendicular” and “substantially perpendicular” refer to a value, amount, or characteristic that departs from exactly parallel or perpendicular, respectively, by less than or equal to 15 degrees, 10 degrees, 5 degrees, 3 degrees, 1 degree, or 0.1 degree.

The method as described above may be accomplished through the use of a computing apparatus. A processor is provided to perform computational analysis for instructions provided. The instruction provided, code, may be written to achieve the desired goal and the processor may access the instructions. In other embodiments, the instructions may be provided directly to the processor. The code may be provided on self-contained apparatus, that are machine readable to allow the method instructions to be performed.

In other embodiments, other components may be substituted for generalized processors. These specifically designed components, known as application specific integrated circuits (“ASICs”) are specially designed to perform the desired task. As such, the ASIC's generally have a smaller footprint than generalized computer processors. The ASIC's, when used in embodiments of the disclosure, may use field programmable gate array technology, that allow a user to make variations in computing, as necessary. Thus, the methods described herein are not specifically held to a precise embodiment, rather alterations of the programming may be achieved through these configurations.

In embodiments, when equipped with a processor, the processor may have arithmetic logic unit (“ALU”), a floating point unit (“FPU”), registers and a single or multiple layer cache. The arithmetic logic unit may perform arithmetic functions as well as logic functions. The floating-point unit may be math coprocessor or numeric coprocessor to manipulate number for efficiently and quickly than other types of circuits. The registers are configured to store data that will be used by the processor during calculations and supply operands to the arithmetic unit and store the result of operations. The single or multiple layer caches are provided as a storehouse for data to help in calculation speed by preventing the processor from continually accessing random access memory (“RAM”).

Aspects of the disclosure provide for the use of a single processor. Other embodiments of the disclosure allow the use of more than a single processor. Such configurations may be called a multi-core processor where different functions are conducted by different processors to aid in calculation speed. In embodiments, when different processors are used, calculations may be performed simultaneously by different processors, a process known as parallel processing.

The processor may be located on a motherboard. The motherboard is a printed circuit board that incorporates the processor as well as other components helpful in processing, such as memory modules (“DIMMS”), random access memory, read only memory, non-volatile memory chips, a clock generator that keeps components in synchronization, as well as connectors for connecting other components to the motherboard. The motherboard may have different sizes according to the needs of the computer architect. To this end, the different sizes, known as form factors, may vary from sizes from a cellular telephone size to a desktop personal computer size. The motherboard may also provide other services to aid in functioning of the processor, such as cooling capacity. Cooling capacity may include a thermometer and a temperature-controlled fan that conveys cooling air over the motherboard to reduce temperature.

Data stored for execution by the processor may be stored in several locations, including the random access memory, read only memory, flash memory, computer hard disk drives, compact disks, floppy disks and solid state drives. For booting purposes, data may be stored in an integrated chip called an EEPROM, that is accessed during start-up of the processor. The data, known as a Basic Input/Output System (“BIOS”), contains, in some example embodiments, an operating system that controls both internal and peripheral components.

Different components may be added to the motherboard or may be connected to the motherboard to enhance processing. Examples of such connections of peripheral components may be video input/output sockets, storage configurations (such as hard disks, solid state disks, or access to cloud-based storage), printer communication ports, enhanced video processors, additional random-access memory and network cards.

The processor and motherboard may be provided in a discrete form factor, such as personal computer, cellular telephone, tablet, personal digital assistant or other component. The processor and motherboard may be connected to other such similar computing arrangement in networked form. Data may be exchanged between different sections of the network to enhance desired outputs. The network may be a public computing network or may be a secured network where only authorized users or devices may be allowed access.

As will be understood, method steps for completion may be stored in the random access memory, read only memory, flash memory, computer hard disk drives, compact disks, floppy disks and solid state drives.

Different input/output devices may be used in conjunction with the motherboard and processor. Input of data may be through a keyboard, voice, Universal Serial Bus (“USB”) device, mouse, pen, stylus, Firewire, video camera, light pen, joystick, trackball, scanner, bar code reader and touch screen. Output devices may include monitors, printers, headphones, plotters, televisions, speakers and projectors.

Although a few embodiments of the disclosure have been described in detail above, those of ordinary skill in the art will readily appreciate that many modifications are possible without materially departing from the teachings of this disclosure. Accordingly, such modifications are intended to be included within the scope of this disclosure as defined in the claims. It is also contemplated that various combinations or sub-combinations of the specific features and aspects of the embodiments described may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure herein should not be limited by the particular embodiments described above.

In the aspects described, a detailed set of petrophysical measurements or properties are propagated to all the wells in the field. This allows the user to derive actionable insights in wells where measurement is not available. Second, it allows the user to build a reservoir model or a set of models that can subsequently be used for prediction. Lastly, it expands the understanding of the value of information/a measurement or service in wells.

In the aspects described, the apparatus and methods provided are easier to operate than conventional apparatus and methods so that the detailed set of petrophysical measurements are determined.

In the aspects described, the provided apparatus and methods do not have the drawbacks discussed above with conventional apparatus, namely the costly drilling and high resolution measurements required for each well in an area.

In the aspects described, downhole tools of known capacities are used to deduce the characteristics of a well without repetitive analysis to ultimately reduce economic costs associated with operations and apparatus described above with conventional tools and conventional analysis.

The aspects described use known downhole measuring techniques without specialized equipment that allows for propagation of characteristics to other wellbores.

In one example embodiment, a method of deriving a geological parameter for at least one well is disclosed. The method may comprise identifying a first data set for a first well that comprises at least a measurement A of the first well and a measurement B of the first well, wherein the measurement A of the first well is a property of interest. The method may also comprise identifying a second data set for a second well, wherein the second set of data comprises a measurement B for the second well and developing a mapping the measurement B of the first well with the measurement A of the first well in order to derive a property of interest of the first well. The method may also comprise deriving the property of interest for a measurement A for the second well from the measurement B of the second well using the mapping developed.

In another example embodiment, the method may be performed wherein the first well is in a same field as the second well.

In another example embodiment, the method may be performed wherein the first well is an analog of the second well.

In another example embodiment, the method may be performed wherein the property of interest of the first well and the property of interest of the second well is at least one of permeability, saturation, clay volume, heterogeneity, anisotropy, elemental concentration, other petrophysical properties, and combinations thereof.

In another example embodiment, the method may be performed wherein the at least one measurement A of the first well and the measurement B of the first well is at least one of an acoustic measurement, nuclear measurement, resistivity measurement, nuclear magnetic resonance spectroscopy measurement and combinations thereof.

In another example embodiment, the method may be performed wherein measurement A of the first well is a high-resolution measurement.

In another example embodiment, the method may be performed wherein the first well is a plurality of wells.

In another example embodiment, the method may be performed wherein the first data set comprises a plurality of measurements A and measurements B for each well of the plurality of wells.

In another example embodiment, the method may further comprise obtaining an actual measurement A and property of interest for the second well.

In another example embodiment, the method may further comparing the derived measurement A of the second well and derived property of interest of the second well to an actual measurement A of the second well and the actual property of interest of the second well.

In one example embodiment, a method of deriving a geological parameter for wells in a field is described. The method may comprise identifying a first data set for at least two first wells that comprises at least a measurement A and a measurement B, wherein the measurement A is a property of interest. The method may also comprise identifying a second data set for at least one second well in the same field, wherein the second set of data comprises a measurement B for the second well. The method may also comprise developing a mapping the measurement B of the at least two first wells with the measurement A of the first two wells in order to derive a property of interest of the first well. The method may also comprise deriving a property of interest for a measurement A for the at least one second well in the same field from the measurement B of the at least one second well using the mapping developed.

The method may also be performed wherein at least one measurement A of the first well is a high-resolution measurement.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may be varied in many ways. Such variations are not to be regarded as a departure from the disclosure, and all such modifications are intended to be included within the scope of the disclosure.

While embodiments have been described herein, those skilled in the art, having benefit of this disclosure, will appreciate that other embodiments are envisioned that do not depart from the inventive scope. Accordingly, the scope of the present claims or any subsequent claims shall not be unduly limited by the description of the embodiments described herein.

What is claimed is:

1. A method of deriving a geological parameter for at least one well, comprising:
identifying a first data set for a first well that comprises at least a measurement A of the first well and a measurement B of the first well, wherein the measurement A of the first well is a property of interest;
identifying a second data set for a second well, wherein the second set of data comprises a measurement B for the second well;
developing a mapping the measurement B of the first well with the measurement A of the first well in order to derive a property of interest of the first well; and
deriving the property of interest for a measurement A for the second well from the measurement B of the second well using the mapping developed.

2. The method of claim 1, wherein the first well is in a same field as the second well.

3. The method of claim 1, wherein the first well is an analog of the second well.

4. The method of claim 1, wherein the property of interest of the first well and the property of interest of the second well is at least one of permeability, saturation, clay volume, heterogeneity, anisotropy, elemental concentration, other petrophysical properties, and combinations thereof.

5. The method of claim 1, wherein the at least one measurement A of the first well and the measurement B of the first well is at least one of an acoustic measurement, nuclear measurement, resistivity measurement, nuclear magnetic resonance spectroscopy measurement and combinations thereof.

6. The method of claim 1, wherein measurement A of the first well is a high-resolution measurement.

7. The method of claim 1, wherein the first well is a plurality of wells.

8. The method of claim 7, wherein the first data set comprises a plurality of measurements A and measurements B for each well of the plurality of wells.

9. The method of claim 1, further comprising:
obtaining an actual measurement A and property of interest for the second well.

10. The method of claim 9, further comprising:
comparing the derived measurement A of the second well and derived property of interest of the second well to an actual measurement A of the second well and the actual property of interest of the second well.

11. A method of deriving a geological parameter for wells in a field, comprising:
identifying a first data set for at least two first wells that comprises at least a measurement A and a measurement B, wherein the measurement A is a property of interest;
identifying a second data set for at least one second well in the same field, wherein the second set of data comprises a measurement B for the second well;
developing a mapping the measurement B of the at least two first wells with the measurement A of the first two wells in order to derive a property of interest of the first well; and
deriving a property of interest for a measurement A for the at least one second well in the same field from the measurement B of the at least one second well using the mapping developed.

12. The method according to claim 11, wherein at least one measurement A of the first well is a high-resolution measurement.
